(19) United States
(12) Patent Application Publication
(10) Pub. No.: US 2007/0045800 A1
(43) Pub. Date: Mar. 1, 2007

(54) Opto-coupler with high reverse breakdown voltage and high isolation potential

(76) Inventors: Brian King, New London, NH (US); Jonathan Googins, Barrington, NH (US); Mark Granoff, Auburn, NH (US); Philip Demaine, Epping, NH (US)

Correspondence Address: FISH & NEAVE IP GROUP;ROPES & GRAY LLP, ONE INTERNATIONAL PLACE, BOSTON, MA, 02110-2624, US

(21) Appl. No.: 11/507,187

(22) Filed: Aug. 21, 2006

Related U.S. Application Data
(60) Provisional application No. 60/709,684, filed on Aug. 19, 2005.

(51) Int. Cl. H01L 33/00; H01L 23/02; H01L 27/15

(52) U.S. Cl. 257/678; 257/80

(57) ABSTRACT

An opto-coupler and a process for fabricating an opto-coupler are disclosed. The opto-coupler includes at least one light-emitting diode and a photodiode for galvanically isolating electric circuits. The optical components are mounted in a yielding material, such as silicone rubber, in a housing. The interior walls are coated with a pigmented yielding coating which includes TiO₂ to enhance light reflection inside the housing and increase the current transfer efficiency of the device. The opto-coupler has a high dielectric breakdown voltage and is immune to radiation. The device can be employed in space applications.

### CROSS-REFERENCE TO RELATED APPLICATIONS

This application claims the benefit of Provisional Application No. 60/709,684, filed on Aug. 19, 2005, the contents of which are incorporated herein by reference in their entirety.

### GOVERNMENT CONTRACT

The U.S. Government has a paid-up license in this invention and the right in limited circumstances to require the patent owner to license others on reasonable terms as provided for by the terms of Contract No. NAS5-00132 awarded by NASA.

### FIELD OF THE INVENTION

The invention is directed to an opto-coupler providing an interface between two galvanically-isolated electrical circuits, and to a method for making an opto-coupler.

### BACKGROUND OF THE INVENTION

An optoelectronic coupling element or opto-coupler, also referred to as opto-isolator or optoelectronic relay, is a semiconductor device that can be used to provide electrical interface between two galvanically-isolated circuits. Opto-couplers typically include a light emitter, such as a light-emitting diode (LED) operating, for example, in the visible or infrared (IR) wavelength range, and a photo-detector (PD), such as a photodiode or a phototransistor, optically coupled to, but galvanically insulated from the LED. The emitter receives an electrical signal which modulates the light emitted by the LED. The modulated light travels across a transparent gap between the LED and the photo-detector, which converts the modulated light back into a modulated electric signal. Below a limit frequency which is determined by the design of the opto-coupler and the connected circuitry, the electrical output waveform will typically closely resemble the electric input waveform. The ratio of the output current through the detector and the input current through the LED is generally referred to as the current transfer ratio (CTR) and tends to have a value of less than 0.1%. The advantages of opto-couplers over mechanical relays are the elimination of any moving parts, their long life, small size, compatibility with semiconductor circuits, and fast response time.

The LED/PD combination is typically mounted in a housing made of a material with a high dielectric strength which is also designed to prevent stray light and environmental contamination from affecting its performance. Conventional opto-couplers provide electrical isolation between input and output terminals of up to several kV. The high-voltage performance tends to be limited by electric breakdown and arcing between input and output.

While the foregoing arrangements are adequate for a number of applications, there is still a need for an opto-coupler providing reliable electric high-voltage isolation between the signal input and output terminals and a high current transfer ratio.

### SUMMARY OF THE INVENTION

The invention addresses the deficiencies of the prior art by, in various embodiments, providing methods and systems for improving the operating characteristic of opto-couplers.

To achieve that, the components of the opto-coupler of the invention are packaged in a yielding space-qualified material to prevent gradual loss of optical and mechanical properties due to the combination of thermal, oxidative and photodegradation processes.

According to one aspect of the invention, an opto-coupler includes a housing and one or more light-emitting diodes (LED) and a photodetector (PD) disposed in the housing, wherein the PD receives light from the LED(s). A coating of a yielding material having a pigment dispersed therein is applied to the inside wall and bottom of the housing, wherein the coating is designed to enhance reflection of the light emitted by the LED(s). The coating has a thickness so as not to contact the LED(s) and the PD. Another yielding, optically transparent filler material is poured into the housing cavity to fill the remaining space between the coated walls and bottom of the housing and to enclose the LED(s) and the PD. A cover layer made of the same material as the yielding coating is applied to the top of the housing, whereby the coating and the cover layer completely enclose the LED(s) and the PD.

According to another aspect of the invention, a process of manufacturing an opto-coupler includes the steps of mounting one or more light-emitting diodes (LED) and a photodetector (PD) in a housing, coating interior surfaces of the housing with a light-reflecting first yielding compound, and filling the space between the coated interior surfaces of the housing with a second yielding compound, thereby encapsulating the LED(s) and the PD. The top opening of the housing is then also covered with the first yielding compound.

Exemplary embodiments of the invention may include one or more of the following features. The yielding material of the coating and/or the filler material may include a silicone-rubber-based material, whereby the material of the coating may be identical to or different from the filler material. The pigment in the coating material includes titanium dioxide (TiO₂), preferably with a composition of approximately 20 parts by weight of pigment to 80 parts by weight of the yielding material. The thickness of the coating selected so that the coating does not to touch the optical surfaces of the LED(s) and the PD. The LED(s) are spaced from the PD by approximately 0.1 mm to approximately 5 mm, preferably between approximately 0.2 mm and 0.5 mm.

In an advantageous embodiment of the invention, the interior of the housing may be primed to promote adhesion of the coating, and the coating is applied sequentially in several thin layers. After each application of an additional layer, the device may advantageously be cured at a temperature of between 40° C. and 60° C.

Further features and advantages of the invention will be apparent from the following description of illustrative embodiments and from the claims.

### BRIEF DESCRIPTION OF THE DRAWINGS

These and other features and advantages of the invention will be more fully understood by the following illustrative description with reference to the appended drawings, in which elements are labeled with like reference designations and which may not be to scale.

FIG. 1 is a perspective top view of an opto-coupler with 2 LEDs and a photodiode in a housing;

FIG. 2 is a perspective cut-open side view of the opto-coupler of FIG. 1;

FIG. 3 shows a schematic circuit diagram for testing the current transfer ratio (CTR) of the opto-coupler of FIG. 1; and

FIG. 4 shows the time response measured with the circuit of FIG. 3;

FIG. 5 is a process flow diagram for manufacture of the opto-coupler according to the invention;

FIG. 6 shows a comparison between the CTR of opto-couplers produced by the process of the invention and a conventional opto-coupler;

FIG. 7 shows tracking between high-voltage diode output current and LED current with changes in operating temperature; and

FIG. 8 illustrates the immunity of the CTR from an applied total ionizing dose.

### DETAILED DESCRIPTION OF CERTAIN ILLUSTRATED EMBODIMENTS

The invention, in various embodiments, provides systems, methods and devices for an opto-coupler with a superior dielectric breakdown voltage and an improved current transfer ratio (CTR) between the signal input and output terminals. More particularly, the opto-coupler employs a reflective coating of the interior of the housing in which the components are mounted and uses a yielding material for encapsulation which reduces stress on the device components.

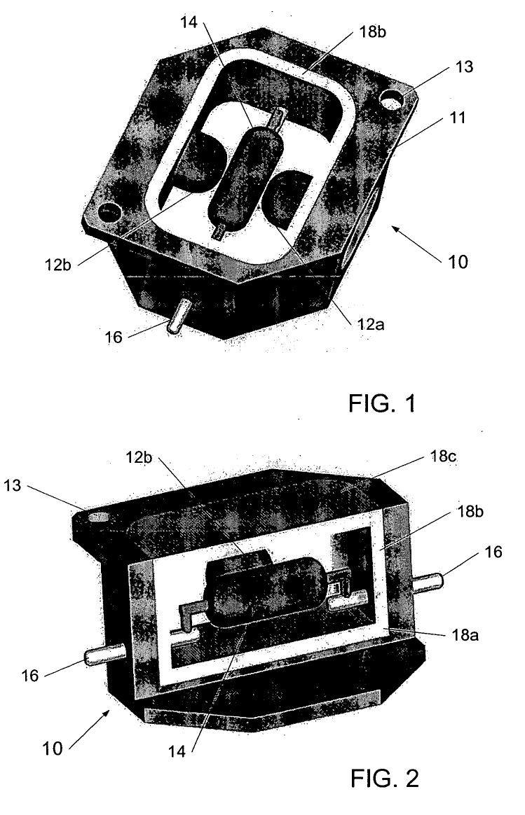

Referring now to FIG. 1, an assembled opto-coupler 10 includes a housing 11 made of Ultem™ which is known to have a high dielectric strength. Ultem™ is a thermoplastic polyetherimide high heat polymer and has exceptional flame resistance with a limiting oxygen index. It has also a stable dielectric constant, outstanding mechanical properties, broad chemical resistance, and excellent machineability. Ultem™ is used, for example, in electrical components, circuit boards, microwave applications, and computer circuitry. The housing 11 is closed at the bottom and has a top flange with two mounting holes 13. As the housing 11 is typically installed on a circuit board (not shown) with the top flange facing the board, a separate cover for the housing is generally not required. Two light-emitting diodes (LED) 12a, 12b facing each other are mounted in side faces of the housing 11, and a high voltage photodiode (PD) 14 is arranged between the LEDs 12a, 12b. The PD 14 is mounted on lead wires 16 extending through insulated feedthroughs in the housing 11. The LEDs 12a, 12b and the PD 14 are located in a common plane, with a small gap between the LEDs 12a, 12b and the PD 14. As seen in FIGS. 1 and 2, the bottom 18a and the walls 18b of the housing 11 are coated with a layer of an opaque, reflecting coating or “paint,” made by addition of titanium dioxide to an otherwise clear and relatively soft (yielding) encapsulant. The LEDs 12a, 12b and the PD 14 are then fully encapsulated in the same clear encapsulant used for producing the “paint”. The top opening in housing 11 is finally covered with the same “paint” used to coat the bottom and walls of the housing 11. Details of the manufacturing process of the opto-coupler of the invention will be described in detail below.

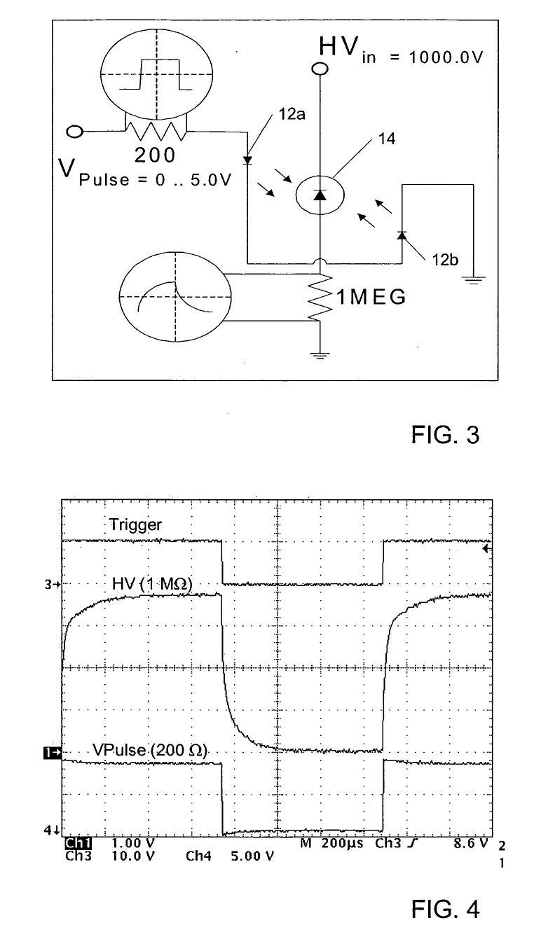

FIG. 3 shows a circuit employed for measuring the temporal response and the current transfer ratio of an exemplary opto-coupler produced with the process according to the invention. The LEDs 12a, 12b are connected in series and forward-biased under an applied square-wave voltage pulse of between 0V and +5V from a trigger circuit. The time dependence of the diode current in response to the voltage pulse is measured by measuring the voltage drop across a test resistor (200Ω) and recorded on as an oscilloscope trace, as shown in FIG. 4. The high-voltage PD 14 is connected in reverse bias to a supply voltage (HVᵢₙ=1000V) via a current-limiting resistor (1MΩ). The electric current flowing through the high voltage diode changes in response to the amount of light produced by the LEDs. This current causes a voltage drop across the 1MΩ resistor which is also recorded on as a separate oscilloscope trace, as shown in FIG. 4. The ratio between the detected current through the PD 14 and the detected current through the LEDs 12a, 12b is then the current transfer ratio, which is a measure of the efficiency of the opto-coupler. It will be understood that a phototransistor can be used instead of a photodiode.

Returning to FIGS. 1 and 2, the encapsulant used for mixing the “paint” and for encapsulating the LEDs 12a, 12b together with the PD 14 is in the present exemplary embodiment a Dow Corning® 93-500 Space Grade vulcanizing, silicone encapsulant, which cures in 24 hours at 25° C. or in less time at elevated temperatures Dow Corning® 93-500 is a solventless silicone material designed for potting, filling, embedding and encapsulating electronic and other equipment for use in the space environment. It is supplied as a nearly colorless, free flowing, low viscosity fluid. It has a dielectric strength of approximately 23 kV/mm and a refractive index of approximately 1.4, which closely matches the refractive index of class and hence reduces reflections at the interface between the glass surfaces of the LEDs and PD and the encapsulant.

Filling the space between the LEDs 12a, 12b and the PD 14 with a dielectric material is advantageous because of the relatively small breakdown voltage of only about 3 kV/mm of dry air., DC 93-500 is supplied in two parts which are mixed with a weight ratio of 10 parts base to 1 part cure agent. To ensure a high dielectric breakdown voltage and to minimize light scattering by the encapsulant, care is taken during mixing to minimize air entrapment. The mixture is therefore preferably de-aired under vacuum until bubbles are no longer detected, about 5 minutes.

The aforementioned “paint” for coating the interior bottom 18a and walls 18b of the housing 11 and for later applying the top layer 18c is prepared by addition of up to 25 wt. % titanium dioxide (TiO₂) powder to the mixed encapsulant. Prior to the addition of the TiO₂ powder, the TiO₂ powder is baked at 80° C. for 2 hours to remove residual moisture. The “paint” mixture needs only to be de-aired once after addition of the TiO₂.

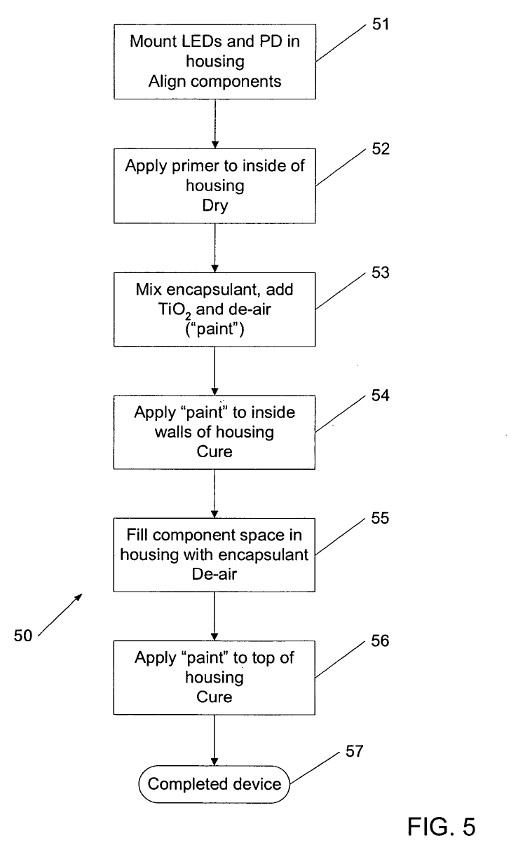

Before addressing the performance of the opto-coupler, the fabrication of the opto-coupler of the invention will now be described with reference to the process flow 50 depicted in FIG. 5. At step 51, the device is assembled by mounting the LEDs 12a, 12b and the PD 14 in housing 11 with a predetermined spacing between the LEDs 12a, 12b and the PD 14,which may range from several tenth of a millimeter, for example 0.1 mm, to several millimeters, for example 5 mm, preferably between approximately 0.2 mm and 0.5 mm. The photodiode 14 is placed midway between and aligned with the LEDs horizontal and vertical axes to maximize light capture. This relationship should be maintained during encapsulation. The components are checked for cleanliness and proper alignment in the housing and then pre-baked for approximately two hours at about 45° C.

At step 52, a primer, such as Dow Corning® DC 1200, is applied to the inside of the housing 11. DC 1200 is a clear, watery primer that promotes bonding between the silicone encapsulant and the contacted surfaces. It can be applied in a thin layer with a fine brush, by dipping or spraying. The primed surface can be air-dried for approximately 15 minutes, but preferably no longer than 2 hours, at room temperature. The surfaces may appear milky or frosty which has no detrimental effect on the adhesion. Dried primer can be removed with a swab dampened with isopropyl alcohol.

At step 53, the “paint” for producing the layers 18a, 18b, 18c is prepared by adding the curing agent (Part B) to the base (Part A) of the DC 93-500 silicone compound in the specified ratio of 1:10 (Part B : Part A). Dried TiO₂ powder (approximately 20-25 wt. %) is added to the combination and then thoroughly mixed and de-aired for approximately 15 minutes. This produces an opaque white “paint” which is then applied in layers in several steps to cover the interior bottom 18a and walls 18b of the opto-coupler housing 11, at step 54. Each layer can be painted separately and be allowed to partially cure for 15 minutes in an oven set at between 45° C. and 55° C. This will firm up the paint so that a different section of the interior can be painted without the prior section sagging. No de-airing is necessary after a section has been painted, although air inclusions in the paint should be avoided.

Advantageously, the bottom 18a of the opto-coupler housing is filled with the paint only to reach the bottom of the LED body. Any paint that contacts the light-transmitting glass surfaces of the LED 12a, 12b and the PD 14 should be removed. After the side walls 18b are painted, the paint covering the bottom 18a and the side walls 18b is preferably fully cured overnight at 45° C.

At this point of the process, on one hand, the opacity of the paint shields the electronic components from external light entering from the sides and the bottom of the housing 11. On the other hand, the TiO₂ in the paint makes the paint highly reflective for the light emitted by the LEDs 12a, 12b, which reduces optical losses and increases the overall current transfer efficiency of the opto-coupler.

The next step of process 50, at step 55, involves encapsulating the components with the DC 93-500 encapsulant. The light-transmitting glass surfaces of the LEDs 12a, 12b and the PD 14 are primed. The primer does not impair the functionality of the cured encapsulant and quite likely prevents the formation of a detrimental air interface between the encapsulant and the glass surfaces. The clear DC 93-500 encapsulant is then filled into the housing cavity up to the top of the LEDs. The mixture is then de-aired and cured, as before, in an oven at between 45° C. and 55° C. More encapsulant can be added to almost fill the housing; however, no de-airing is required. The level of the encapsulant should be high enough to cover the components, but still leave enough space near the top of the housing to accommodate one or more layers of the opaque top paint layer 18c, applied at step 56, and optionally a housing cover. The device can be completed by curing it overnight at 45° C. in an oven, at steps 56, 57.

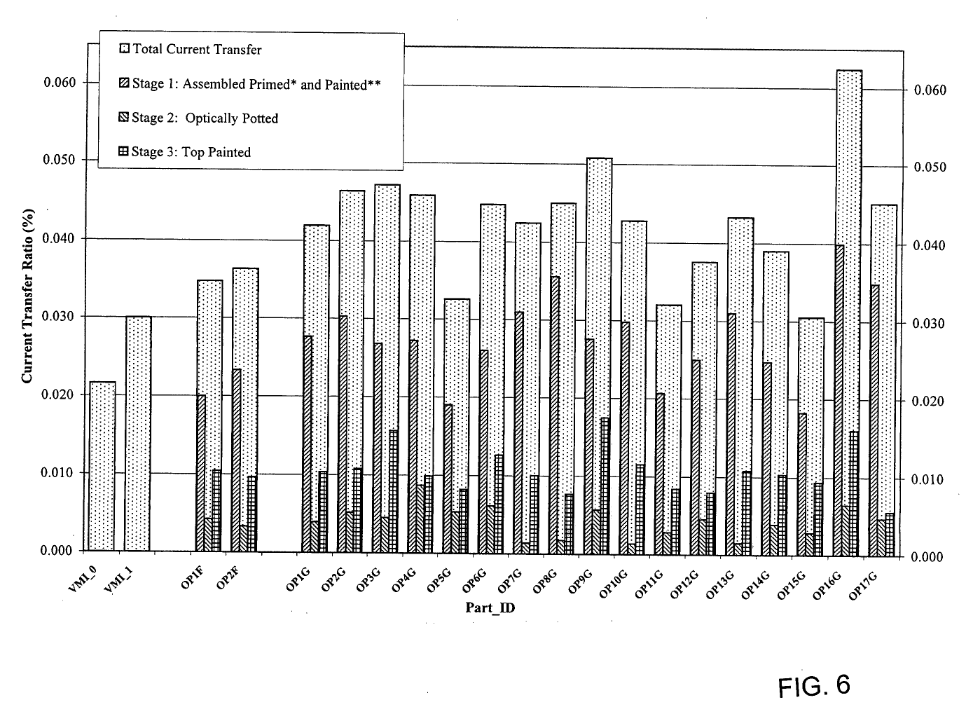

FIG. 6 shows a comparison between a commercially available opto-coupler OC100 supplied by Voltage Multipliers Inc. (VMI), Visalia, Calif. (USA). Two samples of the opto-coupler OC100, labeled VMI_{—}0 and VMI_{—}1, were evaluated. These include, as the opto-coupler of the present invention, two LEDs and one 10 kV high-voltage photodiode, which are encapsulated in a non-yielding (hard) resin-type material. The CTR of these devices is 0.022 and 0.030%, respectively. The other opto-couplers depicted in the diagram of FIG. 6 and labeled OP#Y (#=1, . . . , 17; Y=F and G) were produced with the method of the invention. As can be seen, the CTR of all OP#Y opto-couplers is at least equal to, and in many cases significantly higher than the CTR of the VMI opto-couplers. Both the OP#F-type and the OP#G-type devices employ photodiodes with a reverse breakdown voltage of 15 kV. The spacing between the PG 14 and the symmetrically arranged LEDs 12a, 12b is 1 mm for the OP#F-type device and 0.25 mm for the OP#G-type device. Both device types withstood an isolation test voltage in excess of 25 kV. The data suggest, in spite of significant statistical variations, that a smaller spacing increases the CTR. The results also strongly suggest that the most significant contribution to the overall CTR stems from the opaque TiO₂-pigmented paint layers 18a, 18b applied to the inside of the housing and from the final TiO₂-pigmented top layer 18c. The CTR of the most efficient opto-coupler OP17G is with >0.062% more than twice that of the more efficient VMI device VMI₁₃ 1 (0.03%). The clear DC 93-500 encapsulant does not significantly contribute to the CTR, but is important for increasing the dielectric breakdown (isolation test) voltage. The output current of the PD was observed to be a linear function of the input current of the LEDs, which can be conveniently supplied from a 5 VDC power source. Dielectric breakdown voltages in excess of 25 kV have been measured.

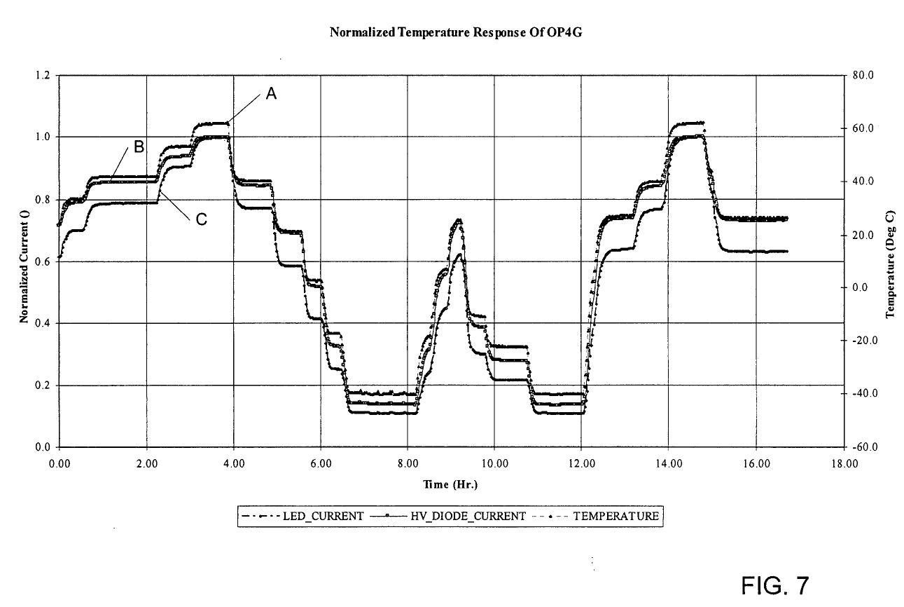

FIG. 7 shows operating parameters of the opto-coupler OP4G shown in FIG. 6 over a wide temperature range between −40° C. and +60° C. The depicted curves show the measured temperature (curve A) over a 17 hour period, as well as the normalized measured LED current (curve B) and the normalized measured PD current (curve C). The results demonstrate that the two respective current curves track each other and the temperature curve, which underlines the thermal stability of the device of the invention. The CTR is a linear function of the device temperature (not illustrated).

This device is intended for use in space applications, for example, in the sweep supply for the PLasma And Supra Thermal Ion Composition (PLASMA), Solar TErrestrial RElations Observatory (STEREO) mission for NASA. To this end, the total ionizing dose susceptibility was tested under an applied bias voltage with the circuit diagram of FIG. 3. Four of the devices listed in FIG. 6 were exposed to a Co-60 environment, with the radiation dose rate for the exposure ranging from 0.1 to 1.0 krads(Si)/hour.

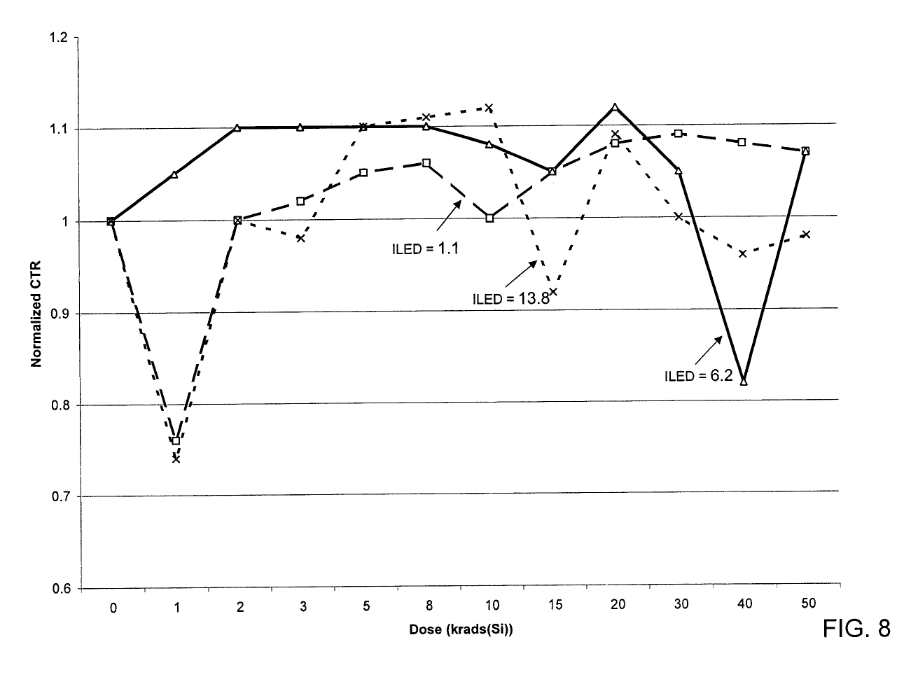

FIG. 8 shows the variation of the normalized current transfer ratio (CTR) for the opto-coupler as a function of the total ionizing dose and for three different input currents to the LEDs (1.1 mA; 6.2 mA; and 13.8 mA, respectively). The CTR is normalized to a value of one before the radiation exposure. As can be seen, there is little change, with dose of the CTR, except for statistically insignificant variations, and all devices were functionally operative and remained within the zero-exposure values up to the highest level tested at 50 krads(Si).

In summary, a fabrication process is disclosed for an opto-coupler with a space-qualified enclosure which has low outgassing, applies little stress to the encapsulated components, and has a small footprint. In spite of the smaller overall package size, the device has a high isolation voltage and a high overall current transfer efficiency. The opaque paint applied to the interior of the package and as a lid before the components are fully encapsulated in the translucent DC 93-500 encapsulant appears to be an important step for improving the device performance over prior art devices.

While the invention has been disclosed in connection with the preferred embodiments shown and described in detail, various modifications and improvements may be made thereto without departing from the spirit and scope of the invention. By way of example, although the illustrative embodiments have been described in conjunction with an opto-coupler using a photodiode, phototransistors can also be employed. The encapsulant may be useful for other electronic applications, where low mechanical stress, a high dielectric breakdown voltage, and radiation immunity are desired.

What is claimed is:

1. An opto-coupler comprising:
a housing having a side wall, a bottom and a top,
at least one light-emitting diode (LED) and a photodetector (PD) disposed in the housing, said PD receiving light from the at least one LED,
a coating applied to an inside of the wall and bottom of the housing, said coating comprising a yielding material and a pigment dispersed in the yielding material and designed to enhance reflection of the light emitted by the at least one LED, said coating having a thickness so as not to contact the at least one LED and the PD,
a yielding, optically transparent filler material filling a remaining space between the coated walls and bottom of the housing and enclosing the at least one LED and the PD, and
a cover layer made of the yielding coating, so that the coating and the cover layer completely enclose the at least one LED and the PD.

2. The opto-coupler of claim 1, wherein the yielding material of the coating and the yielding filler material are identical.

3. The opto-coupler of claim 1, wherein the yielding material of the coating comprises a silicone-rubber-based material.

4. The opto-coupler of claim 1, wherein the yielding filler material comprises a silicone-rubber-based material.

5. The opto-coupler of claim 1, wherein the pigment comprises titanium dioxide (TiO₂).

6. The opto-coupler of claim 1, wherein a spacing between the at least one LED and the PD is in a range from approximately 0.1 mm to approximately 5 mm.

7. The opto-coupler of claim 6, wherein the spacing between the at least one LED and the PD is between approximately 0.2 mm and approximately 0.5 mm.

8. The opto-coupler of claim 1, wherein the coating has a composition of approximately 20 parts by weight of pigment to 80 parts by weight of the yielding material.

9. A process of manufacturing an opto-coupler, comprising the steps of:
mounting at least one light-emitting diode (LED) and a photodetector (PD) in a housing,
coating interior surfaces of the housing with a light-reflecting first yielding compound,
filling a space between the coated interior surfaces of the housing with a second yielding compound, thereby encapsulating the at least one LED and the PD, and covering a top opening of the housing with the first yielding compound.

10. The process of claim 9, wherein coating the interior surfaces comprises sequentially applying several layers of the first yielding compound and curing the applied layers before application of a subsequent layer.

11. The process of claim 9, further comprising the step of priming the interior surfaces before coating.

12. The process of claim 9, wherein the pigment comprises titanium dioxide (TiO₂).

13. The process of claim 9, wherein the first and second yielding compounds comprise silicone rubber.

14. The process of claim 9, wherein coating includes applying the light-reflecting first yielding compound with a thickness so as not to contact optically transmissive surfaces of the at least one LED and the PD.
